(19) United States
(12) Patent Application Publication
(10) Pub. No.: US 2003/0178658 A1
(43) Pub. Date: Sep. 25, 2003

(54) Semiconductor memory and method of manufacture thereof

(76) Inventor: Hiroki Shinkawata, Tokyo (JP)

Correspondence Address: MCDERMOTT, WILL & EMERY, 600 13th Street, N.W., Washington, DC, 20005-3096, US

(21) Appl. No.: 10/330,538

(22) Filed: Dec. 30, 2002

Related U.S. Application Data
(63) Continuation-in-part of application No. 09/479,901, filed on Jan. 10, 2000, now abandoned.

(30) Foreign Application Priority Data
Jul. 13, 1999 (JP) 11-199106

(51) Int. Cl. H01L 29/76

(52) U.S. Cl. 257/295

(57) ABSTRACT

A semiconductor memory for widening the room for layout in the area having a small room for layout such as in a DRAM array, and for solving the problem of unstable resistance due to the contact of capacitor element contacts embedded in a DRAM with the gate electrode at the hole bottom, and a method for manufacturing such a semiconductor device. Since bit-line contact 26 can be made on the element isolating oxide film 1 by using a polysilicon plug-like wiring 25 using phosphorus-doped polysilicon in N-channel transistor portion 120, the room for layout can be widened compared with conventional devices, even for the narrow active region (LDD diffusion layer) 24. In the capacitor element portion 140 required by the embedded device, since the phosphorus-doped polysilicon capacitor contact 31 can make contact with the polysilicon plug-like wiring 29 by using the polysilicon plug-like wiring 29, stable contact with small variation of resistance can be obtained.

### FIELD OF THE INVENTION

The present invention relates to a semiconductor memory and a method of the manufacture thereof, and in particular to a semiconductor memory having a plug-like contact and a method of the manufacture of such a semiconductor memory.

### DESCRIPTION OF RELATED ART

In the recent years, the downsizing of semiconductor memories represented by dynamic random access memories (DRAMs) has been accelerated. Especially in state-of-the-art DRAMs, the shrinkage of their memory cell area requires to make both the capacitor contact and the bitline contact be the self-aligned contact (SAC). In the mainstream capacitor-over-bit-line (COB) structure, since the capacitor contact must be SAC to both the gate electrode wiring and the bit line wiring, etching holes for the both wiring using one SAC is difficult considering that the depth of the capacitor contact is typically about 1 μm. Therefore, in the state-of-the-art DRAMs or the like, the capacitor contact has been formed while decreasing the depth of the contact to be formed at a time, by first making a hole SAC, then forming a lift-up contact using a plug structure, and finally allowing a diameter-decreasing capacitor contact to make contact to the plug.

FIG. 8 shows a sectional view of a conventional semiconductor memory. For the ease of description, the device in FIG. 8 is divided into a semiconductor device having a memory cell portion 80, an N-channel or P-channel transistor portion 82, and an above-gate contact portion 84, and a embedded capacitor portion 86. In FIG. 8, 1 is an element isolating oxide film, 2 is a diffusion layer, 3 is a gate oxide film, 4 is a gate electrode, 5 is an electrode side-wall oxide film, 6 is a silicon nitride film side-wall spacer, 7 is a TEOS oxide film, 8 is a self-aligned hole opening stopper silicon nitride film, 9 is a polysilicon plug, 10 is a plug interlayer insulating film, 11 and 20 are Ti/TiN barrier metals, 12, 22, 26, and 28 are bit-line contacts, 13 is a bit-line interlayer insulating film, 14 is a tungsten bit line, 15 is a capacitor contact, 16 is a capacitor interlayer insulating film, 17 is an under-polysilicon-capacitor electrode, 18 is a capacitor dielectric film, 19 is a polysilicon cell plate, 21 is an LDD diffusion layer, 30 is a bit line, 31 is a capacitor contact, 32 is an under-polysilicon-capacitor electrode, 33 is a capacitor dielectric film, 34 is a polysilicon cell plate, and 35 is a gate electrode.

FIG. 9 shows a plan of each portion shown in FIG. 8. In the above-described method for forming a capacitor contact, since it is required for the bit-line contact 22 and the like to make contact to the active region 20 so as not to contact with the gate electrode 4 on the silicon substrate, there is a problem that the room for layout is extremely small in the area indicated by B, as shown by the N-channel or P-channel transistor portion 82.

On the other hand, when an analog circuit is embedded, a capacitor element is used as the device embedded in the semiconductor memory. Therefore, when an analog circuit portion is embedded in a device having a capacitor such as DRAM, the capacitor element can be formed in the analog circuit portion using the same mask as that for the capacitor such as DRAM. Since this capacitor element has a structure for reading data from the bit line through the gate electrode of the DRAM, there is an area where resistance is unstable.

As FIGS. 8 and 9 show, in the capacitor portion 86 embedded in the DRAM, since the gate electrode (polycide) 35 contacts with the capacitor contact (polysilicon) 31 at the bottom of the hole R (unstable resistance area), resistance becomes unstable. Therefore, a mask has been added, and a capacitor structure such as polysilicon/SiON/polysilicon has been adopted.

As described above, since hole opening by etching using one SAC is difficult, there has been a problem that the room for layout is extremely small when conventional methods for forming a capacitor contact are used for DRAM arrays and the like. Furthermore, to solve the problem of unstable resistance due to the contact of the gate electrode (polycide) 35 and the capacitor contact (polysilicon) 31 at the bottom of the hole R, the use of the conventional method to add a mask is extremely complicated.

### SUMMARY OF THE INVENTION

Therefore, the object of the present invention is to provide a semiconductor memory which can increase the room for layout in the area having a small room for layout such as a DRAM array, by forming a plug-like contact as a local wiring, and can stabilize the resistance by forming a polysilicon/polysilicon structure using the plug-like contact as the local wiring of the capacitor element in the embedded capacitor portion; and to provide a method for manufacturing such a semiconductor memory.

According to a fist aspect of the present invention, there is provided a semiconductor memory comprising a transistor portion of a first conductivity type, the transistor portion of a first conductivity type having a transistor active region, an element isolating region formed adjacently to the transistor active region, a plug-like local wiring using phosphorus-doped polysilicon formed over the transistor active region and the element isolating region, a barrier metal formed on a part of the plug-like local wiring using phosphorus-doped polysilicon, and a bit-line contact formed on the barrier metal, wherein the bit-line contact makes contact to the transistor active region on the element isolating region through the plug-like local wiring using phosphorus-doped polysilicon.

According to a second aspect of the present invention, there is provided a semiconductor memory comprising a transistor portion, the transistor portion having, a transistor active region, an element isolating region formed adjacently to the transistor active region, a barrier metal formed over a part of the transistor active region and a part of the element isolating region, a plug-like local wiring using tungsten or titanium nitride (TiN) formed on the barrier metal, and a bit-line contact formed on the plug-like local wiring using tungsten or TiN, wherein, the bit-line contact makes contact to the transistor active region on the element isolating region through the plug-like local wiring using tungsten or TiN.

According to a third aspect of the present invention, there is provided a method for manufacturing a semiconductor memory comprising a transistor of a first conductivity type comprising the steps of, forming a transistor active region, and an element isolating region adjacent to the transistor active region; forming a plug-like local wiring using phosphorus-doped polysilicon over the transistor active region and the element isolating region; forming a barrier metal on a part of the plug-like local wiring using phosphorus-doped polysilicon; and forming a bit-line contact on the barrier metal, wherein, the bit-line contact makes contact to the transistor active region on the element isolating region through the plug-like local wiring using phosphorus-doped polysilicon.

The above and other objects, effects, features and advantages of the present invention will become more apparent from the following description of the embodiments thereof taken in conjunction with the accompanying drawings.

### BRIEF DESCRIPTION OF THE DRAWINGS

FIG. 1 shows a sectional view of a semiconductor memory according to the Embodiment 1 of the present invention.

FIG. 2 shows a sectional view of a semiconductor device according to the Embodiment 2 of the present invention.

FIG. 3 shows a plan corresponding to FIG. 1.

FIG. 4 shows a sectional view of a semiconductor device according to the Embodiment 3 of the present invention.

FIG. 5 shows a sectional view of a semiconductor device according to the Embodiment 4 of the present invention.

FIG. 6 shows a sectional view of a semiconductor device according to the Embodiment 5 of the present invention.

FIG. 7 shows a sectional view of a semiconductor device according to the Embodiment 6 of the present invention.

FIG. 8 shows a sectional view of a conventional semiconductor memory.

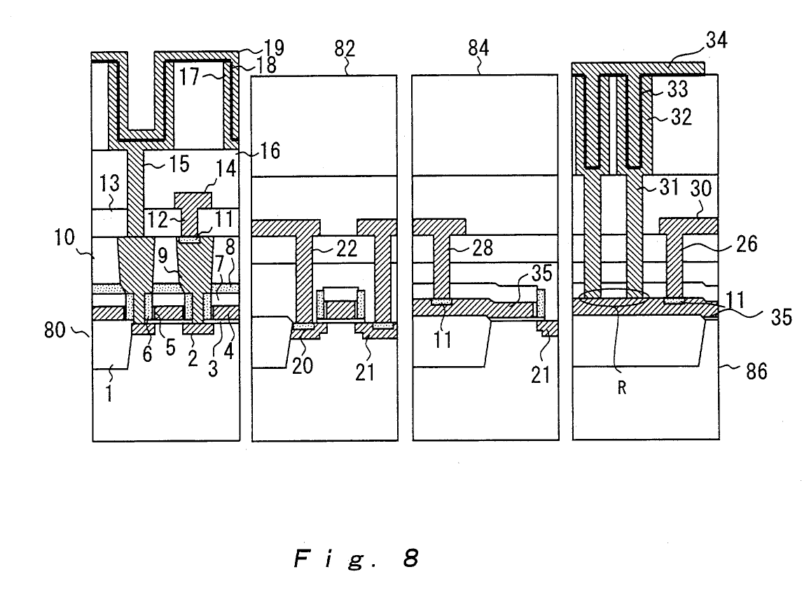

FIG. 9 shows a plan of each portion shown in FIG. 8.

### DETAILED DESCRIPTION OF THE PREFERRED EMBODIMENTS

Embodiments of the present invention will be described below with reference to the accompanying drawings. It is noted that the same reference symbols in the drawings denote the same or corresponding components.

### EMBODIMENT 1

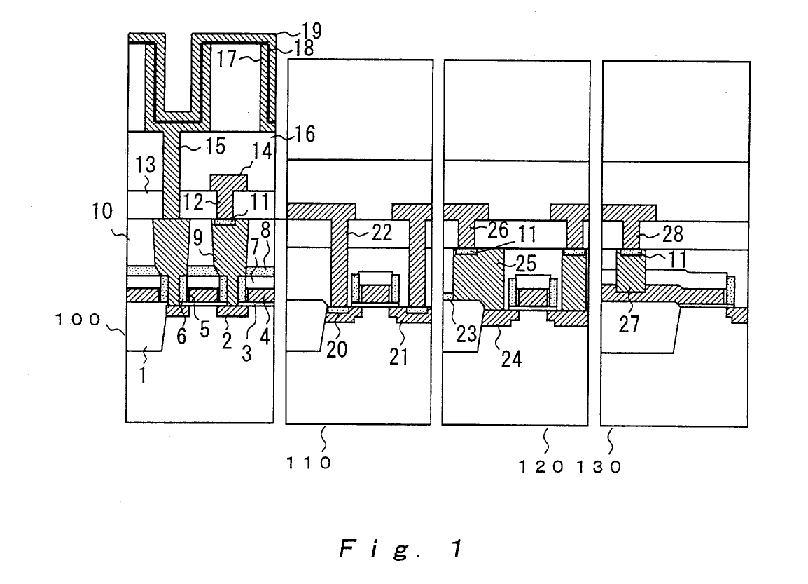

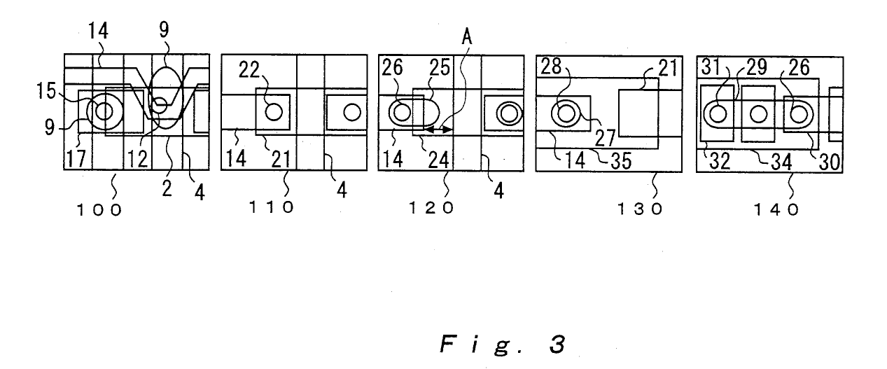

FIG. 1 shows a sectional view of a semiconductor memory according to the Embodiment 1 of the present invention, and FIG. 3 shows a plan corresponding to FIG. 1. In FIGS. 1 and 3, the semiconductor device is divided into a memory cell portion 100, a P-type transistor portion 110, an N-type transistor portion 120, and an above gate contact portion 130, for facilitating description. In FIG. 1, I is an element isolating oxide film, 2 is a diffusion layer, 3 is a gate oxide film, 4 is a gate electrode, 5 is a gated electrode side-wall oxide film, 6 is a silicon nitride film side-wall spacer, 7 is a TEOS oxide film, 8 is a self-aligned hole opening stopper silicon nitride film, 9 and 27 are polysilicon plugs, 10 is a plug interlayer insulating film, 11 and 20 are Ti/TiN barrier metals, 12, 22, 26, and 28 are bit-line contacts, 13 is a bit-line interlayer insulating film, 14 is a tungsten bit line, 15 is a capacitor contact, 16 is a capacitor interlayer insulating film, 17 is a polysilicon under-silicon-capacitor electrode, 18 is a capacitor dielectric film, 19 is a polysilicon cell plate, 21 and 24 are LDD diffusion layer, 23 is a stopper silicon nitride film, and 25 is a polysilicon plug-like wiring.

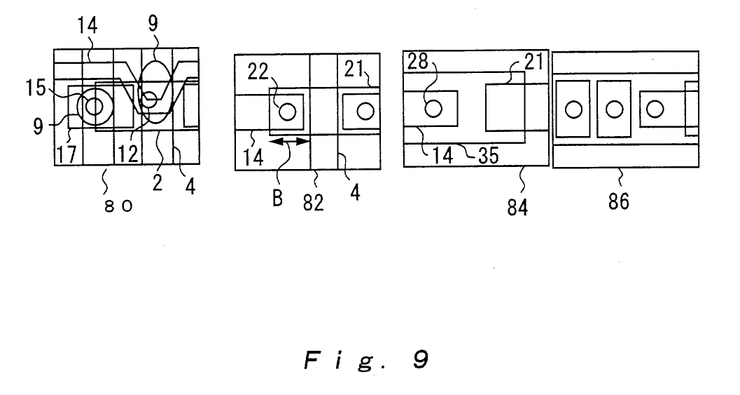

As FIGS. 1 and 3 show, in the Embodiment 1 of the present invention, phosphorus-doped polysilicon is used for the polysilicon plug 9 of the memory cell portion 100. In this case, a plug-like local wiring (polysilicon plug-like wiring) 25 using phosphorus-doped polysilicon can be used in the N-channel transistor portion 120. Since bit-line contact 26 can be made on the element isolating oxide film 1 by this polysilicon plug-like wiring 25, the room for layout can be widened compared with the area shown by B of the N-channel or P-channel transistor portion 82 in FIG. 9, as the area shown by A of the N-channel transistor portion 120 in FIG. 3, even for the narrow active region (LDD diffusion layer) 24.

According to the Embodiment 1, as described above, since the polysilicon plug-like wiring 25 using phosphorus-doped polysilicon can be used in the N-channel transistor portion 120, bit-line contact 26 can be made on the element isolating oxide film 1, and the room for layout can be widened compared with conventional devices even for the narrow active region (LDD diffusion layer) 24. That is, the bit-line contact 26 can be formed even if A (see the N-channel transistor portion 120 in FIG. 3) <<B (see the N-channel or P-channel transistor portion 82 in FIG. 9).

### EMBODIMENT 2

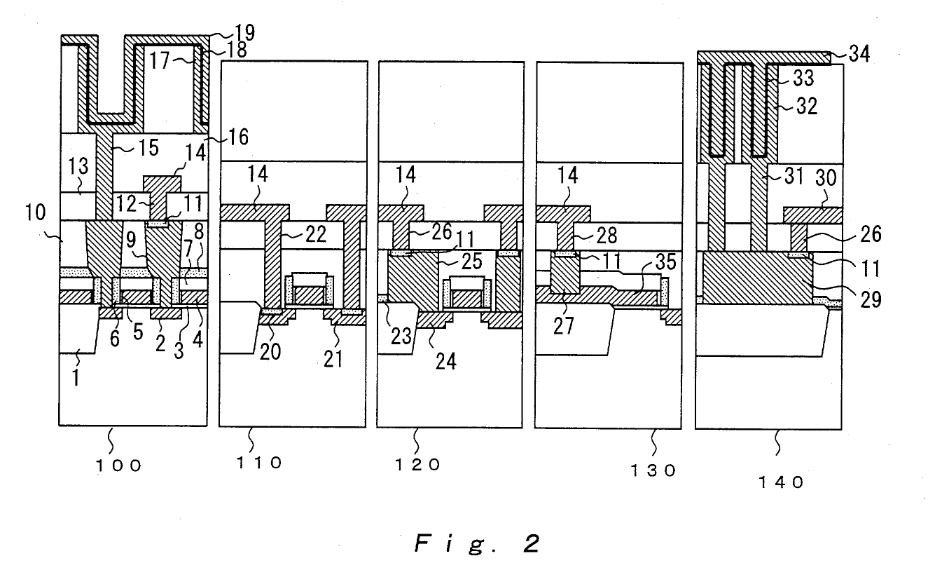

FIG. 2 shows a sectional view of a semiconductor device according to the Embodiment 2 of the present invention. In FIG. 2, since the parts indicated by the same symbols as in FIG. 1 have the same functions, the description of such parts will be omitted. In FIG. 2, 29 is a polysilicon plug-like wiring, 30 is a bit line, 31 is a capacitor contact, 32 is an under-polysilicon-capacitor electrode, 33 is a capacitor dielectric film, 34 is a polysilicon cell plate, and 35 is a gate wiring.

In the Embodiment 2, a capacitor element portion 140 required by the embedded device is added to the Embodiment 1. As FIG. 2 shows, since the phosphorus-doped polysilicon capacitor contact 31 can make contact with the polysilicon plug-like wiring 29 by using the phosphorusdoped polysilicon plug-like local wiring (polysilicon plug-like wiring) 29, stable contact with small variation of resistance can be obtained.

According to the Embodiment 2 as described above, in the capacitor element portion 140 required by the embedded device is added to the Embodiment 1, since the phosphorus-doped polysilicon capacitor contact 31 can make contact with the polysilicon plug-like wiring 29 by using the polysilicon plug-like wiring 29, stable contact with small variation of resistance can be obtained.

### EMBODIMENT 3

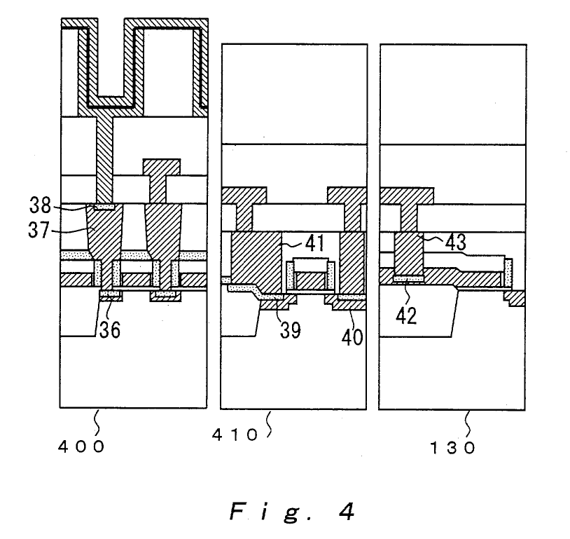

FIG. 4 shows a sectional view of a semiconductor device according to the Embodiment 3 of the present invention. In FIG. 4, since the parts indicated by the same symbols as in FIGS. 1-3 have the same functions, the description of such parts will be omitted. In FIG. 4, 36, 38, 39, and 42 are Ti/TiN or Ti barrier metals, 37 and 43 are tungsten plugs, 40 is an LDD diffusion layer, 41 is a tungsten or TiN plug-like wiring, 400 is a memory cell portion, and 410 is an N-channel transistor portion and P-channel transistor portion.

In the Embodiment 3 of the present invention, tungsten or TiN is used for the plug-like contact (tungsten or TiN plug) 9 of the memory cell portion 400, and a Ti/TiN or Ti barrier metal 36 is used underneath the tungsten or TiN plug 9, respectively. When TiN is used for a plug material, the barrier metal is Ti. In this case, a plug-like local wiring using tungsten or TiN (tungsten or TiN plug-like wiring) 41 can be used for the N-channel transistor portion and the P-channel transistor portion 410, and a Ti/TiN or Ti barrier metal 39 can be used underneath the tungsten or TiN plug-like wiring 41, respectively. Although a plug-like local wiring cannot be used in the P-channel transistor portion 110 in the Embodiment 1, the above-described tungsten or TiN plug-like wiring 41 enables to make the bit-line contact 26 on the element isolating film 1 in the P-channel transistor portion 110 in the same way as in the N-channel transistor portion 120. Therefore, even for a narrow active region (LDD diffusion layer) 24, as in the area indicated by A of the N-channel transistor portion 120 in FIG. 3, the room for layout can be widened compared with the area indicated by B of the P-channel transistor portion 82 in FIG. 9. Furthermore, although the Ti/TiN is required between the bit-line contact 26 and the polysilicon plug-like wiring 25 in the Embodiment 1, as shown in the N-channel transistor portion 120 in FIG. 1, the barrier metal 11 is not required in the Embodiment 3 by using the tungsten or TiN plug-like wiring 41, as shown in the N-channel transistor portion and the P-channel transistor portion 410 in FIG. 4.

According to the Embodiment 3, as described above, since the tungsten or TiN plug-like wiring 41 using tungsten or TiN can be used in the N-channel transistor portion and P-channel transistor portion 410, bit-line contact 26 can be made on the element isolating oxide film 1, and the room for layout can be widened compared with conventional devices even for the narrow active region (LDD diffusion layer) 24. Furthermore, the barrier metal 11 is not required by using the tungsten or TiN plug-like wiring 41.

### EMBODIMENT 4

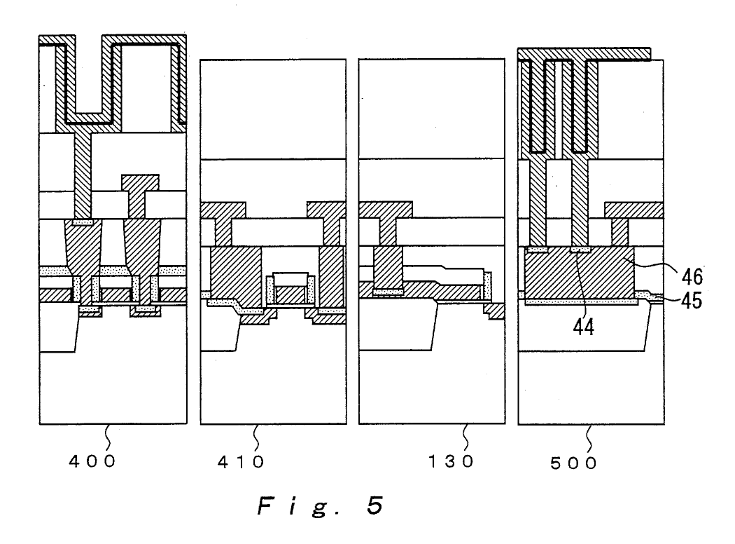

FIG. 5 shows a sectional view of a semiconductor device according to the Embodiment 4 of the present invention. In FIG. 5, since the parts indicated by the same symbols as in FIGS. 1-4 have the same functions, the description of such parts will be omitted. In FIG. 5, 44 and 45 are Ti/TiN or Ti barrier metals, and 46 is a tungsten or TiNi plug-like wiring, respectively.

In the Embodiment 4, a capacitor element portion 500 required by the embedded device is added to the Embodiment 3. As FIG. 5 shows, since the capacitor contact 31 of phosphorus-doped polysilicon can make contact with the tungsten or TiN plug-like wiring 46 through the Ti/TIN or Ti barrier metal 44, respectively, by using the tungsten or TiN plug-like local wiring, stable contact with little variation of resistance can be obtained.

According to the Embodiment 4 as described above, in the capacitor element portion 400 required by the embedded device added to the Embodiment 3, since the capacitor contact 31 of phosphorus-doped polysilicon can make contact with the tungsten or TiN plug-like wiring 46 through the Ti/TiN or Ti barrier metal 44, respectively, by using the tungsten TiN plug-like wiring 46, stable contact with little variation of resistance can be obtained.

### EMBODIMENT 5

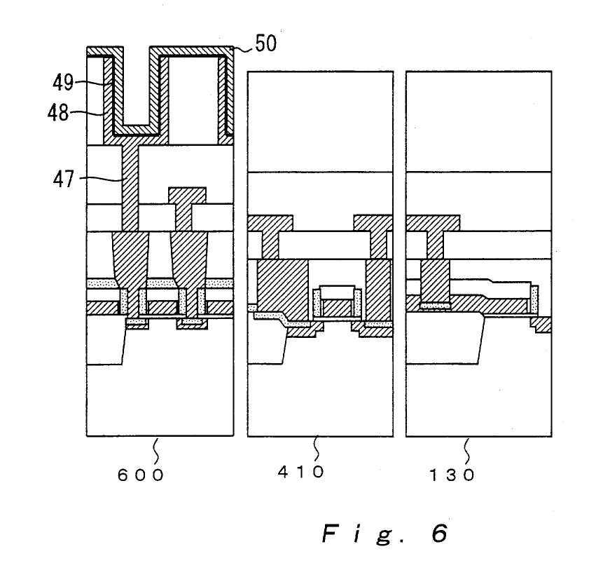

FIG. 6 shows a sectional view of a semiconductor device according to the Embodiment 5 of the present invention. In FIG. 6, since the parts indicated by the same symbols as in FIGS. 1-5 have the same functions, the description of such parts will be omitted. In FIG. 6, 47 is a tungsten capacitor contact, 48 is an under-capacitor electrode made of Pt, RuO₂/Ru, tungsten W, Ti, TiN or IrO₂/Ir, 49 is a capacitor dielectric film of a high dielectric constant, and 50 is a cell plate made of Pt, RuO₂/Ru, tungsten W, Ti, TiN or IrO₂/Ir.

In the Embodiment 5, a tungsten capacitor contact 57 can be used in the Embodiment 3 by using ferroelectric or highly dielectric materials, such as Ta₂O₅, (Ba, Sr)TiO₃, and PZT for the capacitor dielectric (capacitor dielectric film of a high dielectric constant) 49 of the memory cell portion 600. This results in the omission of the Ti/TiN or Ti barrier metal 38 of the contact to be connected to the tungsten or TiN plug-like local wiring (tungsten or TiN plug) 37 as shown in the memory cell portion 600 of FIG. 6, unlike the memory cell 400 of FIG. 4.

According to the Embodiment 5 as described above, in addition to the Embodiment 3, a tungsten capacitor contact 57 can be used by using ferroelectric or highly dielectric materials, such as Ta₂O₅, (Ba, Sr)TiO₃, and PZT for the capacitor dielectric (capacitor dielectric film of a high dielectric constant) 49 of the memory cell portion 600, thereby the Ti/TiN or Ti barrier metal 38 of the contact to be connected to the tungsten or TiN plug-like local wiring (tungsten or TiN plug) 37 can be omitted.

### EMBODIMENT 6

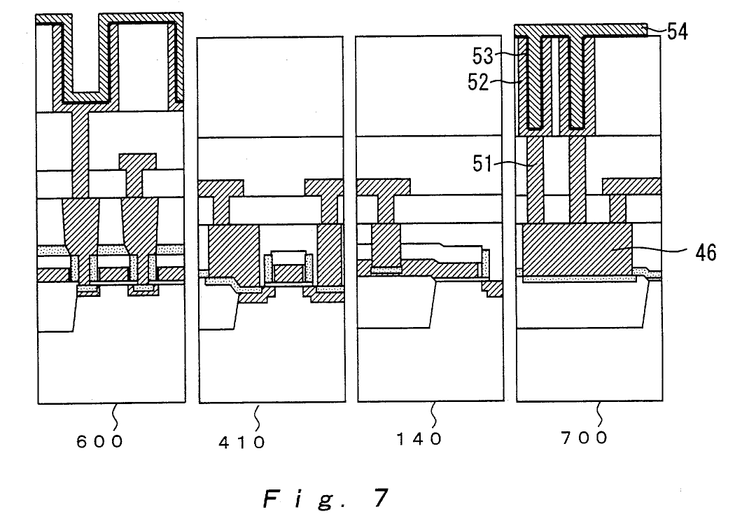

FIG. 7 shows a sectional view of a semiconductor device according to the Embodiment 6 of the present invention. In FIG. 7, since the parts indicated by the same symbols as in FIGS. 1-6 have the same functions, the description of such parts will be omitted. In FIG. 7, 51 is a tungsten capacitor contact, 52 is an under-capacitor electrode made of Pt, RuO₂/Ru, tungsten W, Ti, TiN or IrO₂/Ir, 53 is a capacitor dielectric film of a high dielectric constant, and 54 is a cell plate made of Pt, RuO₂/Ru, tungsten W, Ti, TiN or IrO₂/Ir.

In the Embodiment 6, a capacitor element portion 700 required by the embedded device is added to the Embodiment 5. As FIG. 7 shows, since the tungsten capacitor contact 51 can make contact with the tungsten or TiN plug-like wiring 46 by using the tungsten or TiN plug-like local wiring (tungsten or TiN plug-like wiring) 46 without the Ti/TiN or Ti barrier metal, stable contact with small variation of resistance can be obtained.

According to the Embodiment 6 as described above, in the capacitor element portion 700 required by the embedded device added to the Embodiment 5, since the tungsten capacitor contact 51 can make contact with the tungsten or TiN plug-like wiring 46 without the Ti/TiN or Ti barrier metal by using the tungsten or TiN plug-like wiring 46, stable contact with little variation of resistance can be obtained.

According to the present invention, as described above, there are provided a semiconductor memory having a widened room for layout on the area with a small room for layout such as DRAM arrays by forming a plug-like contact as a local wiring, and having a stabilized resistance by forming a polysilicon/polysilicon structure using the plug-like contact as the local wiring for the capacitor element in the embedded capacitor portion; and the method for manufacturing such a device.

Here, the semiconductor memory may further comprise a embedded capacitor element portion, wherein the capacitor element portion comprises a plug-like local wiring using polysilicon; and a capacitor contact using phosphorus-doped polysilicon formed on the plug-like local wiring using polysilicon, and the capacitor contact using phosphorus-doped polysilicon makes direct contact to the plug-like local wiring using polysilicon.

Here, the semiconductor memory may further comprise a embedded capacitor element portion, wherein the capacitor element portion comprises a plug-like local wiring using tungsten or TiN; a barrier metal formed over a part of the plug-like local wiring using tungsten; and a capacitor contact using phosphorus-doped polysilicon formed on the barrier metal, and the capacitor contact using phosphorus-doped polysilicon makes contact to the plug-like local wiring using tungsten or TiN through the barrier metal.

Here, the semiconductor memory may further comprise a memory cell portion, the memory cell portion having, a plug-like contact using tungsten or TiN, a capacitor contact using tungsten formed on the plug-like contact using tungsten or TiN, and an under-capacitor electrode using a ferroelectric material connected to the capacitor contact using tungsten.

Here, the semiconductor memory may further comprise a embedded capacitor element portion, wherein the capacitor element portion comprises a plug-like local wiring using tungsten or TiN; and a capacitor contact using tungsten formed on the plug-like local wiring using tungsten or TiN, and the capacitor contact using tungsten makes direct contact to the plug-like local wiring using tungsten or TiN.

According to a fourth aspect of the present invention, there is provided a method for manufacturing a semiconductor memory comprising a transistor portion comprising the steps of, forming a transistor active region, and an element isolating region adjacent to the transistor active region; forming a barrier metal over a part of the transistor active region and a part of the element isolating region; forming a plug-like local wiring using tungsten or TiN on the barrier metal; and forming a bit-line contact on the plug-like local wiring using tungsten or TiN, wherein, the bitline contact makes contact to the transistor active region on the element isolating region through the plug-like local wiring using tungsten or TiN.

The present invention has been described in detail with respect to various embodiments, and it will now be apparent from the foregoing to those skilled in the art that changes and modifications may be made without departing from the invention in its broader aspects, and it is the invention, therefore, in the appended claims to cover all such changes and modifications as fall within the true spirit of the invention.

The entire disclosure of Japanese Patent Application No. 11-199106 filed on Jul. 13, 1999 including specification, claims, drawings and summary are incorporated herein by reference in its entirety.

What is claimed is:

1. A semiconductor memory comprising a transistor portion of a first conductivity type, said transistor portion of a first conductivity type having
a transistor active region,
an element isolating region formed adjacently to said transistor active region,
a plug-like local wiring using phospohorus-doped polysilicon formed directly on said transistor active region and said element isolating region,
a barrier metal formed on a part of said plug-like local wiring using phosphorus-doped polysilicon, and
a bit-line contact formed on said barrier metal,
wherein said bit-line contact makes contact to said transistor active region on said element isolating region through said plug-like local wiring using phosphorus-doped silicon,
the semiconductor memory further comprising an embedded capacitor element portion, wherein said capacitor element portion comprises
a plug-like local wiring using polysilicon; and
a capacitor contact using phosphorus-doped polysilicon formed on said plug-like local wiring using polysilicon, and
said capacitor contact using phosphorus-doped polysilicon makes direct contact to said plug-like local wiring using polysilicon.

2. A semiconductor memory comprising a transistor portion, said transistor portion having,
a transistor active region,
an element isolating region formed adjacently to said transistor active region,
a barrier metal formed directly on a part of said transistor active region and a part of said element isolating region,
a plug-like local wiring using tungsten or TiN formed on said barrier metal, and
a bit-line contact formed on said plug-like local wiring using tungsten or TiN, wherein,
said bit-line contact makes contact to said transistor active region on said element isolating region through said plug-like local wiring using tungsten or TiN.

3. The semiconductor memory according to claim 2 further comprising a embedded capacitor element portion, wherein said capacitor element portion comprises
a plug-like local wiring using tungsten or TiN;
a barrier metal formed over a part of said plug-like local wiring using tungsten or TiN; and
a capacitor contact using phosphorus-doped polysilicon formed on said barrier metal, and
said capacitor contact using phosphorus-doped polysilicon makes contact to said plug-like local wiring using tungsten or TiN through said barrier metal.

4. The semiconductor memory according to claim 2 further comprising a memory cell portion, said memory cell portion having,
a plug-like contact using tungsten or TiN,
a capacitor contact using tungsten formed on said plug-like contact using tungsten or TiN, and
an under-capacitor electrode using a ferroelectric material connected to said capacitor contact using tungsten.

5. The semiconductor memory according to claim 4 further comprising a embedded capacitor element portion, wherein
said capacitor element portion comprises
a plug-like local wiring using tungsten or TiN; and
a capacitor contact using tungsten formed on said plug-like local wiring using tungsten or TiN, and
said capacitor contact using tungsten makes direct contact to said plug-like local wiring using tungsten or TiN.
